(19) United States
(12) Patent Application Publication
(10) Pub. No.: US 2025/0347726 A1
(43) Pub. Date: Nov. 13, 2025

(54) ELECTROMAGNETIC WAVE MEASURING APPARATUS, METHOD, AND RECORDING MEDIUM

(71) Applicant: ADVANTEST CORPORATION, Tokyo (JP)

(72) Inventor: Takao SAKURAI, Miyagi (JP)

(73) Assignee: ADVANTEST CORPORATION, Tokyo (JP)

(21) Appl. No.: 19/170,466

(22) Filed: Apr. 4, 2025

(30) Foreign Application Priority Data
May 8, 2024 (JP) 2024-075928

(51) Int. Cl. G01R 29/08

(52) U.S. Cl. CPC G01R 29/0878; G01R 29/0892

(57) ABSTRACT

An electromagnetic wave measuring apparatus includes an interference signal acquiring section, an accumulating and averaging section, a frequency spectrum outputting section, an optical frequency spectrum converting section, and an optical frequency spectrum average outputting section. The interference signal acquiring section acquires an interference signal between a post-irradiation electromagnetic wave and a reference electromagnetic wave. The accumulating and averaging section accumulates interference waveforms, by a number of every one or more, that the interference signal has and outputs an averaged result of the accumulation. The frequency spectrum outputting section outputs a frequency spectrum of an output from the accumulating and averaging section. The optical frequency spectrum converting section converts the frequency spectrum into an optical frequency spectrum. The optical frequency spectrum average outputting section outputs an averaged result of the optical frequency spectrum.

### BACKGROUND OF THE INVENTION

### Field of the Invention

The present invention relates to measuring repeated interference waveforms.

### Description of the Related Art

There has conventionally been known a technique in which a measuring target is measured by acquiring interfering light as a result of interference between an infrared light beam from a light source and a light beam generated when the measuring target is irradiated with the infrared light beam (see Japanese Patent Application Publication Nos. 2012-002793 and 2013-537307, for example).

The interfering light includes interference waveforms repeated therein. There has hence also been known a technique in which random noises are reduced by accumulating interference waveforms, that is, synchronously adding interference waveforms. More precisely, the interference waveforms can be accumulated (accumulated “n” times) and then averaged (i.e. divided by n) to cause the random noises to cancel each other and decrease (i.e. to 1/root (n)), while the magnitude of the signals remains the same.

It is however required that the interference waveforms each have a fixed phase to reduce the random noises by accumulating the interference waveforms. This is for the reason that if the interference waveforms each have a variable phase, the signals in the interference waveforms may also cancel each other.

However, the duration for the phase of each of the interference waveforms to be considered fixed is short (see S. Okubo, et.al., “Ultra-broadband dual-comb spectroscopy across 1.0-1.9 μm”, Applied Physics Express, Jul. 14, 2015, 8, 082402 and I. Coddington et.al., “Cohrent linear optical sampling at 15 bits of resolution”, Optics Letters, Jul. 15, 2009, Vol. 34, No. 14, p. 2153-2155, for example). This may reduce the number of interference waveforms that can be accumulated, and the random noises cannot be sufficiently reduced.

There has hence also been known a technique in which every one of the interference waveforms is corrected in phase (see M. L. Forman et.al., “Correction of Asymmetric Interferograms Obtained in Fourier Spectroscopy”, Journal of the Optical Society of America, January 1966, Vol. 56, Number 1, p. 59-63 and I. Coddington et.al., “Coherent dual-comb spectroscopy at high signal-to-noise ratio”, Physical Review A, Oct. 12, 2010, Vol. 82, Issue 4, 043817, for example). However, such phase correction requires complex signal processing in which interference waveforms in the time domain are converted into waveforms in the frequency domain, corrected in phase, and then converted back into waveforms in the time domain. It is therefore difficult to process in real time the interference waveforms that are repeated at high speed.

### SUMMARY OF THE INVENTION

As described above, there is a problem that since the duration for the phase of each of the interference waveforms to be considered fixed is short, the random noises cannot be sufficiently reduced by accumulating the interference waveforms. Also, as described above, every one of the interference waveforms may be corrected in phase to solve the problem above, but it brings about a new problem that complex signal processing is required.

It is hence an object of the present invention to reduce random noises in interference waveforms without correcting every one of the interference waveforms in phase even when the duration for the phase of each of the interference waveforms to be considered fixed may be short.

According to the present invention, an electromagnetic wave measuring apparatus, includes: an interference signal acquiring section arranged to acquire an interference signal between a post-irradiation electromagnetic wave generated when an irradiation target having a measuring target is irradiated with a pre-irradiation electromagnetic wave and a reference electromagnetic wave having a repetition frequency different from a repetition frequency of the pre-irradiation electromagnetic wave by a predetermined differential frequency; an accumulating and averaging section arranged to accumulate interference waveforms, by a number of every one or more, that the interference signal has and to output an averaged result of the accumulation; a frequency spectrum outputting section arranged to output a frequency spectrum of an output from the accumulating and averaging section; an optical frequency spectrum converting section arranged to convert the frequency spectrum into an optical frequency spectrum; and an optical frequency spectrum average outputting section arranged to output an averaged result of the optical frequency spectrum.

According to the thus constructed electromagnetic wave measuring apparatus, an interference signal acquiring section acquires an interference signal between a post-irradiation electromagnetic wave generated when an irradiation target having a measuring target is irradiated with a pre-irradiation electromagnetic wave and a reference electromagnetic wave having a repetition frequency different from a repetition frequency of the pre-irradiation electromagnetic wave by a predetermined differential frequency. An accumulating and averaging section accumulates interference waveforms, by a number of every one or more, that the interference signal has and outputs an averaged result of the accumulation. A frequency spectrum outputting section outputs a frequency spectrum of an output from the accumulating and averaging section. An optical frequency spectrum converting section converts the frequency spectrum into an optical frequency spectrum. An optical frequency spectrum average outputting section outputs an averaged result of the optical frequency spectrum.

According to the electromagnetic wave measuring apparatus of the present invention, the number may be fixed.

According to the electromagnetic wave measuring apparatus of the present invention, the number may be variable, and the optical frequency spectrum average outputting section may be arranged to output an averaged result of the optical frequency spectrum weighted by the number.

According to the electromagnetic wave measuring apparatus of the present invention, a plurality of the frequency spectrum outputting sections may be provided, and the frequency spectrum outputting sections may be each arranged to output a frequency spectrum of an averaged result of the accumulation for each separate group of interference waveforms.

According to the electromagnetic wave measuring apparatus of the present invention, the optical frequency spectrum average outputting section may be arranged to output an ensemble averaged result of the optical frequency spectrum.

According to the electromagnetic wave measuring apparatus of the present invention, waveforms of the post-irradiation electromagnetic wave may be acquired by dual-comb spectroscopy.

According to the electromagnetic wave measuring apparatus of the present invention, waveforms of the post-irradiation electromagnetic wave may be acquired by terahertz time domain spectroscopy.

According to the electromagnetic wave measuring apparatus of the present invention, waveforms of the post-irradiation electromagnetic wave may be acquired by pump-probe method.

According to the electromagnetic wave measuring apparatus of the present invention, the irradiation target may be gas.

According to the electromagnetic wave measuring apparatus of the present invention, the irradiation target may be housed in a gas cell.

According to the electromagnetic wave measuring apparatus of the present invention, a concentration of the measuring target may be measured.

According to the electromagnetic wave measuring apparatus of the present invention, the irradiation target may be liquid or solid.

According to the electromagnetic wave measuring apparatus of the present invention, a presence of the measuring target may be measured.

According to the present invention, an electromagnetic wave measuring method, includes: acquiring an interference signal between a post-irradiation electromagnetic wave generated when an irradiation target having a measuring target is irradiated with a pre-irradiation electromagnetic wave and a reference electromagnetic wave having a repetition frequency different from a repetition frequency of the pre-irradiation electromagnetic wave by a predetermined differential frequency; accumulating interference waveforms, by a number of every one or more, that the interference signal has; outputting an averaged result of the accumulating; outputting a frequency spectrum of an output from the outputting of the averaged result; converting the frequency spectrum into an optical frequency spectrum; and outputting an averaged result of the optical frequency spectrum.

The present invention is a non-transitory computer-readable medium including a program of instructions for execution by a computer to perform an electromagnetic wave measuring process with using an electromagnetic wave measuring apparatus including an interference signal acquiring section arranged to acquire an interference signal between a post-irradiation electromagnetic wave generated when an irradiation target having a measuring target is irradiated with a pre-irradiation electromagnetic wave and a reference electromagnetic wave having a repetition frequency different from a repetition frequency of the pre-irradiation electromagnetic wave by a predetermined differential frequency, the electromagnetic wave measuring process, including: accumulating interference waveforms, by a number of every one or more, that the interference signal has; outputting an averaged result of the accumulating; outputting a frequency spectrum of an output from the outputting of the averaged result; converting the frequency spectrum into an optical frequency spectrum; and outputting an averaged result of the optical frequency spectrum.

### BRIEF DESCRIPTION OF THE DRAWINGS

FIG. 1 shows the configuration of an electromagnetic wave measuring apparatus 1 according to an embodiment of the present invention;

FIG. 2 shows waveforms of the interference signal;

FIGS. 3 (a), 3 (b) and 3 (c) show an interference signal (FIG. 3 (a)), an averaged result of accumulation (FIG. 3 (b)), and an optical frequency spectrum (FIG. 3 (c)); and

FIG. 4 shows an output from the optical frequency spectrum average outputting section 19.

### DESCRIPTION OF THE PREFERRED EMBODIMENT

A preferred embodiment of the present invention will hereinafter be described with reference to the accompanying drawings.

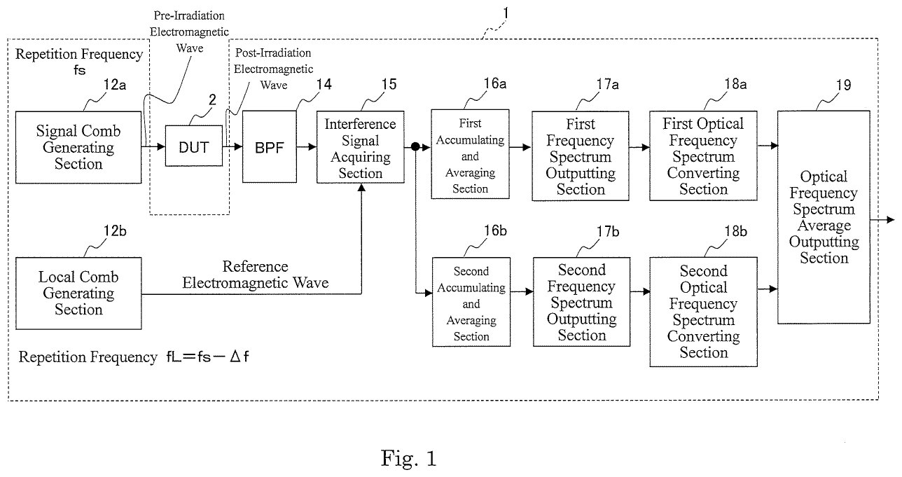

FIG. 1 shows the configuration of an electromagnetic wave measuring apparatus 1 according to an embodiment of the present invention. The electromagnetic wave measuring apparatus 1 according to the embodiment of the present invention is arranged to measure an irradiation target having a measuring target.

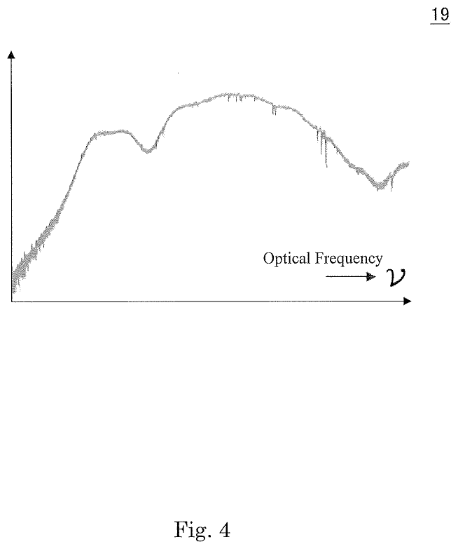

For example, the irradiation target is gas housed in a gas cell (DUT 2 in the embodiment of the present invention). In more detail, gas flows into and out of the gas cell. It is noted that the gas has a measuring target (e.g. molecules in the gas). The electromagnetic wave measuring apparatus 1 may also be arranged to measure the concentration of the measuring target. The method of measuring the concentration of each measuring target is well known and will not be described. For example, from the depth of an absorption line (see FIG. 4), the concentration of the measuring target can be derived by Lambert-Beer's law.

The electromagnetic wave measuring apparatus 1 according to the embodiment of the present invention includes a signal comb generating section 12a, a local comb generating section 12b, a band-pass filter 14, an interference signal acquiring section 15, a first accumulating and averaging section 16a, a second accumulating and averaging section 16b, a first frequency spectrum outputting section 17a, a second frequency spectrum outputting section 17b, a first optical frequency spectrum converting section 18a, a second optical frequency spectrum converting section 18b, and an optical frequency spectrum average outputting section 19.

The signal comb generating section 12a is arranged to generate a pre-irradiation signal comb (a pre-irradiation electromagnetic wave before irradiation of the irradiation target). The local comb generating section 12b is arranged to generate a local comb. The pre-irradiation signal comb and the local comb are optical combs. Irradiating the irradiation target housed in the DUT 2 with the pre-irradiation electromagnetic wave causes a post-irradiation electromagnetic wave to be obtained. The electromagnetic wave measuring apparatus 1 is arranged to measure the measuring target based on the post-irradiation electromagnetic wave. The waveform of the post-irradiation electromagnetic wave is acquired by dual-comb spectroscopy.

For example, the pre-irradiation signal comb has a repetition frequency of fs. For example, the local comb has a repetition frequency of fL. Note here that the local comb (reference electromagnetic wave) has a repetition frequency different from the repetition frequency fs of the pre-irradiation signal comb by a predetermined differential frequency Δf (=fs−fL). It is noted that the frequencies of the pre-irradiation signal comb and the local comb are roughly the frequency of light.

The pre-irradiation signal comb, when the irradiation target (gas) within the DUT (gas cell) 2 is irradiated therewith, penetrates through the DUT 2 to be a post-irradiation signal comb (post-irradiation electromagnetic wave). Like the pre-irradiation signal comb, the post-irradiation signal comb is also an optical comb. It is noted that the post-irradiation signal comb is provided to the band-pass filter 14 and components that have passed therethrough are provided to the interference signal acquiring section 15.

It is here assumed that the power of light with which the irradiation target within the DUT 2 is irradiated changes to be lower (implying light absorption) at a predetermined frequency corresponding to the measuring target.

The band-pass filter 14 is arranged to pass a signal of a band near the predetermined frequency corresponding to the measuring target. Note here that the passband of the band-pass filter 14 is set to be equal to or lower than a predetermined value to reduce ailiasing.

That is, the frequency difference between the post-irradiation signal comb and the local comb increases in steps of Δf like 0, Δf, 2Δf, . . . , while decreases in steps of Δf after the maximum value fL/2 is reached. The passband of the band-pass filter 14 is hence set such that the frequency difference between the post-irradiation signal comb and the local comb is equal to or higher than zero but equal to or lower than fL/2 or equal to or higher than fL/2 but equal to or lower than fL.

For example, a case is considered in which when the frequency of the post-irradiation signal comb is mfs (where m is a positive integer), it is equal to the frequency of the local comb. In this case, the passband of the band-pass filter 14 is within the range from the frequency mfs to the frequency mfs+(½)M1fs (where M1Δf=fL and M1 is a positive integer). Note here that mfs<(the predetermined frequency corresponding to the measuring target)<mfs+(½)M1fs.

The interference signal acquiring section 15 is arranged to acquire an interference signal between the post-irradiation signal comb and the local comb (reference electromagnetic wave). Since the predetermined differential frequency Δf has a relatively low value, the post-irradiation signal comb and the local comb generate beats. The interference signal acquiring section 15 is, for example, an optical coupler, the interference signal acquiring section 15 arranged to be provided with the post-irradiation signal comb and the local comb through the polarization maintaining fiber and an optical attenuator.

The interference signal can be said to be a result of the waveform of the post-irradiation electromagnetic wave acquired by pump-probe method.

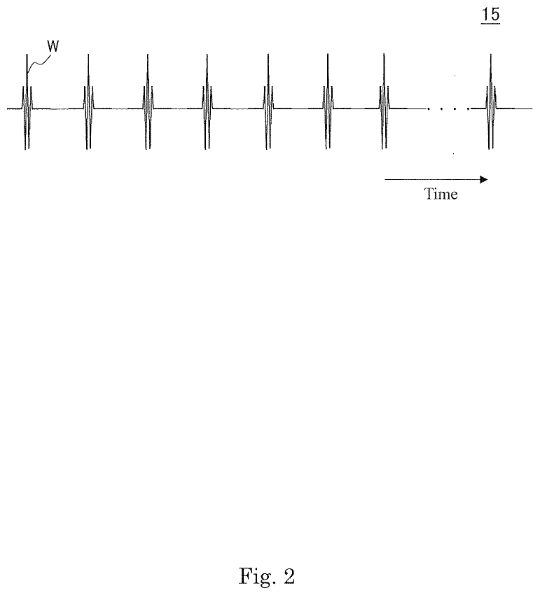

FIG. 2 shows waveforms of the interference signal. Note here that in FIG. 2, the vertical axis represents signal (e.g. in voltage [V]), while the horizontal axis represents time (e.g. in millisecond).

The interference signal acquired by the interference signal acquiring section 15 has multiple interference waveforms W.

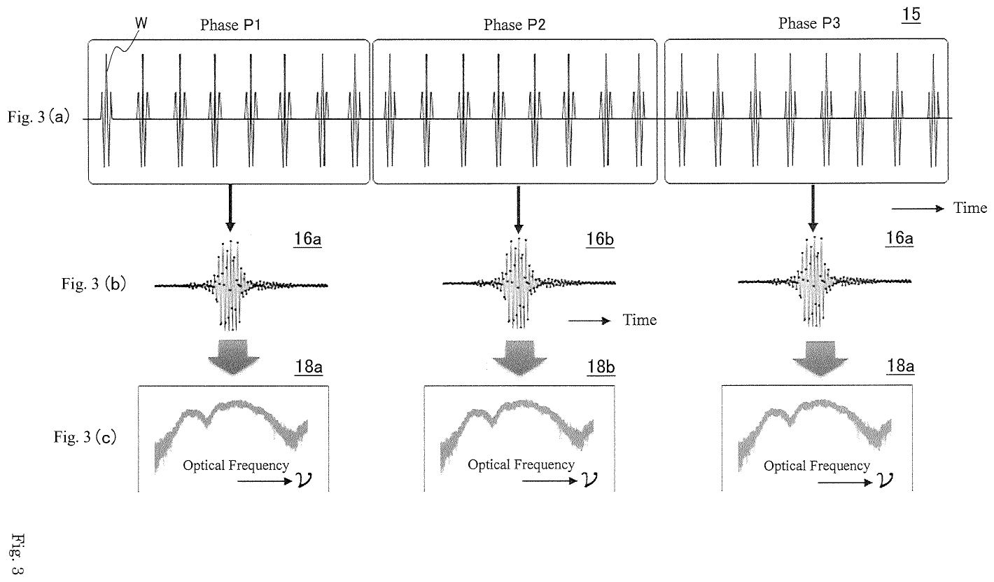

FIGS. 3 (a), 3 (b) and 3 (c) show an interference signal (FIG. 3 (a)), an averaged result of accumulation (FIG. 3 (b)), and an optical frequency spectrum (FIG. 3 (c)).

The first accumulating and averaging section 16a and the second accumulating and averaging section 16b are each arranged to accumulate the interference waveforms W, by a number N of every one or more, that the interference signal has and to output an averaged result of the accumulation.

Referring to FIGS. 3 (a) and 3 (b), the first accumulating and averaging section 16a and the second accumulating and averaging section 16b are each arranged to accumulate the interference waveforms W by a certain number N (=8) of every ones and to output an averaged result of the accumulation. For example, the first accumulating and averaging section 16a is arranged to accumulate the first to eighth interference waveforms W from the left in FIG. 3 (a) and to output an averaged result of the accumulation. Further, the second accumulating and averaging section 16b is arranged to accumulate the ninth to sixteenth interference waveforms W from the left in FIG. 3 (a) and to output an averaged result of the accumulation. Further, the first accumulating and averaging section 16a is arranged to accumulate the seventeenth to twenty-fourth interference waveforms W from the left in FIG. 3 (a) and to output an averaged result of the accumulation. Thus, the first accumulating and averaging section 16a and the second accumulating and averaging section 16b are each arranged to output an averaged result of the accumulation for each separate group of interference waveforms W.

It is noted that while FIG. 3 illustrates an example in which the number N equals 8, the number N may be any number as long as it is 1 or larger.

However, if the number N is small, the number of Fourier transforms performed in the first frequency spectrum outputting section 17a and the second frequency spectrum outputting section 17b (i.e. a value obtained by dividing the total number of interference waveforms W by the number N) increases and therefore the computation load increases. It is therefore necessary for the number N to have a reasonably large value (e.g. N equals 8 or larger).

On the other hand, if the number N is too large, the phase of interference waveforms W to be accumulated deviates. Further, an excessively large amount of memory capacity is required to record the data of the interference waveforms W. In addition, an extended period of time is required to transfer the data of the interference waveforms W (about 400 thousand points per waveform) to the first accumulating and averaging section 16a and the second accumulating and averaging section 16b. It is therefore necessary for the number N not to have an excessively large value (e.g. N equals 32 or smaller).

The first frequency spectrum outputting section 17a is arranged to output a frequency spectrum of an output from the first accumulating and averaging section 16a. The second frequency spectrum outputting section 17b is arranged to output a frequency spectrum of an output from the second accumulating and averaging section 16b. The frequency spectrums can be obtained through, for example, Fourier transform. It is noted that the frequency spectrums do not have information on the phase of the interference waveforms W.

There are multiple (two) frequency spectrum outputting sections, that is, the first frequency spectrum outputting section 17a and the second frequency spectrum outputting section 17b. The frequency spectrum outputting sections are each arranged to output a frequency spectrum of an averaged result of the accumulation for each separate group of interference waveforms. For example, the first frequency spectrum outputting section 17a is arranged to output a frequency spectrum of an averaged result of the accumulation for the first to eighth interference waveforms W from the left in FIG. 3 (a), and further to output a frequency spectrum of an averaged result of the accumulation for the seventeenth to twenty-fourth interference waveforms W from the left in FIG. 3 (a). The second frequency spectrum outputting section 17b is arranged to output a frequency spectrum of an averaged result of the accumulation for the ninth to sixteenth interference waveforms W from the left in FIG. 3 (a).

The first optical frequency spectrum converting section 18a is arranged to convert a frequency spectrum output from the first frequency spectrum outputting section 17a into an optical frequency spectrum (see FIG. 3 (c)). The second optical frequency spectrum converting section 18b is arranged to convert a frequency spectrum output from the second frequency spectrum outputting section 17b into an optical frequency spectrum (see FIG. 3 (c)).

The principle of converting a frequency spectrum into an optical frequency spectrum will be described. In this conversion, the frequency fRF of the frequency spectrum is converted into the optical frequency vopt of the optical frequency spectrum.

First, the optical frequencies v1 and v2 of a particular absorption line are precisely known from, for example, a database. The frequencies of a particular absorption line are observed as RF frequencies fa1 and fa2 in a frequency spectrum obtained based on an interference signal. The optical frequencies v1 and v2 and the RF frequencies fa1 and fa2 are used to obtain an optical frequency vcoin and a scaling factor M at which the mode frequencies of the post-irradiation signal comb and the local comb match.

The optical frequencies v1 and v2 are expressed as in formula 1) and formula 2) below.

$$v 1 = vcoin + fa 1 \cdot M \qquad 1 )$$

$$v 2 = vcoin + fa 2 \cdot M \qquad 2 )$$

The formula 1) and formula 2) above can be deformed to obtain a scaling factor M as in formula 3) below and an optical frequency vcoin as in formula 4) below.

$$M = ( v 1 - v 2 ) / ( fa 1 - fa 2 ) \qquad 3 )$$

$$vcoin = v 1 - fa 1 \cdot M \qquad 4 )$$

Accordingly, the frequency fRF of the frequency spectrum can be converted into vopt of the optical frequency spectrum as in formula 5) below.

$$vopt = vcoin + fRF \cdot M \qquad 5 )$$

It is noted that the electromagnetic wave measuring apparatus 1 according to the embodiment of the present invention includes the two accumulating and averaging sections (i.e. the first accumulating and averaging section 16a and the second accumulating and averaging section 16b), the two frequency spectrum outputting sections (i.e. the first frequency spectrum outputting section 17a and the second frequency spectrum outputting section 17b), and the two optical frequency spectrum converting sections (i.e. the first optical frequency spectrum converting section 18a and the second optical frequency spectrum converting section 18b). Instead, the electromagnetic wave measuring apparatus 1 according to the embodiment of the present invention may include three or more accumulating and averaging sections, three or more frequency spectrum outputting sections, and three or more optical frequency spectrum converting sections. Note here that the electromagnetic wave measuring apparatus 1 according to the embodiment of the present invention may include one accumulating and averaging section, one frequency spectrum outputting section, and one optical frequency spectrum converting section.

The optical frequency spectrum average outputting section 19 is arranged to output an averaged result (e.g. ensemble averaged result) of the optical frequency spectrums output from the optical frequency spectrum converting sections. The optical frequency spectrum average outputting section 19 is arranged to output an averaged result of, for example, an output from the first optical frequency spectrum converting section 18a (for the first to eighth interference waveforms W from the left and the seventeenth to twenty-fourth interference waveforms W from the left in FIG. 3 (a)) and an output from the second optical frequency spectrum converting section 18b (for the ninth to sixteenth interference waveforms W from the left in FIG. 3 (a)).

It is here assumed that the first to eighth interference waveforms from the left in FIG. 3 (a) can be considered to have a constant phase P1, the ninth to sixteenth interference waveforms from the left in FIG. 3 (a) can be considered to have a constant phase P2, and the seventeenth to twenty-fourth interference waveforms from the left in FIG. 3 (a) can be considered to have a constant phase P3. Note here that the phases P1, P2, and P3 should have their respective different values. Even in such a case, since the optical frequency spectrums output from the optical frequency spectrum converting sections do not have information on the phases of the interference waveforms W, there is no problem even if the phases of the interference waveforms W may be different from each other, whereby it is possible to reduce random noises.

It is noted that the optical frequency spectrum average outputting section 19 is not arranged to obtain an average of the frequency spectrums. This is for the reason that the frequency band of the output from the first frequency spectrum outputting section 17a differs from the frequency band of the output from the second frequency spectrum outputting section 17b due to a change in the state of phase synchronization between the post-irradiation signal comb and the local comb. On the other hand, the optical frequency band of the output from the first optical frequency spectrum converting section 18a and the optical frequency band of the output from the second optical frequency spectrum converting section 18b remain equal to each other. Accordingly, the optical frequency spectrum average outputting section 19 is arranged to output an averaged result of the optical frequency spectrums output from the optical frequency spectrum converting sections.

FIG. 4 shows an output from the optical frequency spectrum average outputting section 19. Note here that in FIG. 4, the vertical axis represents signal (e.g. in voltage [V]), while the horizontal axis represents optical frequency v.

Next will be described an operation according to the embodiment of the present invention.

The pre-irradiation signal comb, when the irradiation target (gas) within the DUT (gas cell) 2 is irradiated therewith from the signal comb generating section 12a, penetrates through the DUT 2 to be a post-irradiation signal comb. The post-irradiation signal comb is provided to the band-pass filter 14 and components that have passed therethrough are provided to the interference signal acquiring section 15. A local comb is also provided from the local comb generating section 12b to the interference signal acquiring section 15.

An interference signal between the post-irradiation signal comb (components passing through the band-pass filter 14) and the local comb (reference electromagnetic wave) is acquired by the interference signal acquiring section 15 (see FIGS. 2 and 3 (a)).

The interference signal is provided to the first accumulating and averaging section 16a and the second accumulating and averaging section 16b by every N (=8) interference waveforms W, and an averaged result of the accumulation is output (see FIG. 3 (b)). For example, the first to eighth, the ninth to sixteenth, and the seventeenth to twenty-fourth interference waveforms W from the left in FIG. 3 (a) are provided, respectively, to the first accumulating and averaging section 16a, the second accumulating and averaging section 16b, and the first accumulating and averaging section 16a, and averaged results of the respective accumulations are output (see FIG. 3 (b)).

The output from the first accumulating and averaging section 16a is provided to the first frequency spectrum outputting section 17a, and a frequency spectrum is output. The output from the first frequency spectrum outputting section 17a is provided to the first optical frequency spectrum converting section 18a to be converted into an optical frequency spectrum (see FIG. 3 (c)).

The output from the second accumulating and averaging section 16b is provided to the second frequency spectrum outputting section 17b, and a frequency spectrum is output. The output from the second frequency spectrum outputting section 17b is provided to the second optical frequency spectrum converting section 18b to be converted into an optical frequency spectrum (see FIG. 3 (c)).

The output from the first accumulating and averaging section 16a (an averaged result of accumulation of the first to eighth interference waveforms W from the left in FIG. 3 (a)) is provided to the first frequency spectrum outputting section 17a to undergo Fourier transform, and thereby a frequency spectrum is output. Since the Fourier transform requires an extended period of time, a further interference signal (the ninth to sixteenth interference waveforms W from the left in FIG. 3 (a)) is output from the interference signal acquiring section 15 during the Fourier transform in the first frequency spectrum outputting section 17a.

The further interference signal (the ninth to sixteenth interference waveforms W from the left in FIG. 3 (a)) is provided to the second accumulating and averaging section 16b, and an averaged result of accumulation of the further interference signal is output. The averaged result of the accumulation is provided to the second frequency spectrum outputting section 17b to undergo Fourier transform, and thereby a frequency spectrum is output. Since the Fourier transform also requires an extended period of time, a further next interference signal (the seventeenth to twenty-fourth interference waveforms W from the left in FIG. 3 (a)) is output from the interference signal acquiring section 15 during the Fourier transform in the second frequency spectrum outputting section 17b.

However, at the time when the further next interference signal starts to be output, the Fourier transform in the first frequency spectrum outputting section 17a has been completed, which allows the first frequency spectrum outputting section 17a to process the further next interference signal. That is, the output of the further next interference signal is provided to the first accumulating and averaging section 16a, and an averaged result of the accumulation is output. The averaged result of the accumulation is provided to the first frequency spectrum outputting section 17a to undergo Fourier transform, and thereby a frequency spectrum is output. It is thus possible to prevent stagnation of the processing in the frequency spectrum outputting sections due to the Fourier transform requiring an extended period of time.

It is noted that even if the number N may be larger, three or more accumulating and averaging sections, three or more frequency spectrum outputting sections, and three or more optical frequency spectrum converting sections can be provided to prevent stagnation of the processing in the frequency spectrum outputting sections due to the Fourier transform requiring an extended period of time.

Outputs from the first optical frequency spectrum converting section 18a and the second optical frequency spectrum converting section 18b (see FIG. 3 (c)) are provided to the optical frequency spectrum average outputting section 19, and an averaged result (e.g. ensemble averaged result) of the optical frequency spectrums is output (see FIG. 4).

In accordance with the embodiment of the present invention, the frequency spectrums output from the first frequency spectrum outputting section 17a and the second frequency spectrum outputting section 17b do not have information on the phases of the interference waveforms W. It is therefore possible to reduce random noises in the interference waveforms W without correcting every one of the interference waveforms in phase even when the duration for the phase of each of the interference waveforms W to be considered fixed may be short (e.g. for the case where the phase P1 of the first to eighth interference waveforms W from the left in FIG. 3 (a), the phase P2 of the ninth to sixteenth interference waveforms W from the left in FIG. 3 (a), and the phase P3 of the seventeenth to twenty-fourth interference waveforms W from the left in FIG. 3 (a) are different from each other).

Also, in accordance with the embodiment of the present invention, since there are two frequency spectrum outputting sections (the first frequency spectrum outputting section 17a and the second frequency spectrum outputting section 17b), it is possible to prevent stagnation of the processing in the frequency spectrum outputting sections due to the Fourier transform requiring an extended period of time.

It is noted that the embodiment of the present invention can have the following various variations.

### First Variation

The irradiation target may be liquid or solid. For example, the presence of the irradiation target is measured. For example, an FTIR is used, as an example in which the irradiation target is solid, to measure absorption (1.4 um band) by OH groups of an optical fiber. Alternatively, an FTIR is used, as an example in which the irradiation target is liquid, to determine, for example, whether water is contained based on whether or not absorption by OH groups occurs.

### Second Variation

The waveform of the post-irradiation electromagnetic wave may be acquired by terahertz time domain spectroscopy instead of dual-comb spectroscopy. In this case, the signal comb generating section 12a and the local comb generating section 12b are replaced, respectively, with terahertz generators (which have their respective different repetition frequencies), and the interference signal acquiring section 15 is replaced with a terahertz detector.

### Third Variation

In the embodiment of the present invention, the first accumulating and averaging section 16a and the second accumulating and averaging section 16b are each arranged to accumulate the interference waveforms W by a certain number N (=8) of every ones and to output an averaged result of the accumulation. However, the number N may be variable. Note here that in this case, the optical frequency spectrum average outputting section 19 is arranged to output an averaged result of the optical frequency spectrums weighted by the number N.

For example, the first accumulating and averaging section 16a may be arranged to output an averaged result of the accumulation of eight waveforms (referred to as A1), the second accumulating and averaging section 16b may be arranged to output an averaged result of the accumulation of sixteen waveforms (referred to as A2), and the first accumulating and averaging section 16a may be further arranged to output an averaged result of the accumulation of twenty-four waveforms (referred to as A3). That is, the number N may have variables of 8, 16, and 24.

Here, the frequency spectrum obtained when Al is provided to the first frequency spectrum outputting section 17a is referred to as f1, the frequency spectrum obtained when A2 is provided to the second frequency spectrum outputting section 17b is referred to as f2, and the frequency spectrum obtained when A3 is provided to the first frequency spectrum outputting section 17a is referred to as f3.

Further, the optical frequency spectrum obtained when f1 is provided to the first optical frequency spectrum converting section 18a is referred to as opf1, the optical frequency spectrum obtained when f2 is provided to the second optical frequency spectrum converting section 18b is referred to as opf2, and the optical frequency spectrum obtained when f3 is provided to the first optical frequency spectrum converting section 18a is referred to as opf3.

In such a case, the optical frequency spectrum average outputting section 19 is arranged to output an averaged result of the optical frequency spectrums weighted by the number N, that is, ( 8/48)×opf1+( 16/48)×opf2+( 24/48)×opf3. Note here that 48=8+16+24, that is, the total number of waveforms for which the averaged result of the accumulation is to be obtained.

The above-described embodiment may also be implemented as follows. A computer including a CPU, a hard disk, and a medium (USB memory, CD-ROM, or the like) reading device is caused to read a medium with a program recorded thereon that achieves the above-described components (e.g. the first accumulating and averaging section 16a, the second accumulating and averaging section 16b, the first frequency spectrum outputting section 17a, the second frequency spectrum outputting section 17b, the first optical frequency spectrum converting section 18a, the second optical frequency spectrum converting section 18b, and the optical frequency spectrum average outputting section 19) and install the program in the hard disk. The above-described features can also be achieved in this manner.

### DESCRIPTION OF REFERENCE NUMERALS

1 Electromagnetic Wave Measuring Apparatus
2 DUT (Gas Cell)
12a Signal Comb Generating Section
12b Local Comb Generating Section
14 Band-Pass Filter
15 Interference Signal Acquiring Section
16a First Accumulating and Averaging Section
16b Second Accumulating and Averaging Section
17a First Frequency Spectrum Outputting Section
17b Second Frequency Spectrum Outputting Section
18a First Optical Frequency Spectrum Converting Section
18b Second Optical Frequency Spectrum Converting Section
19 Optical Frequency Spectrum Average Outputting Section
W Waveforms
v Optical Frequency

What is claimed is:

1. An electromagnetic wave measuring apparatus, comprising:
an interference signal acquiring section arranged to acquire an interference signal between a post-irradiation electromagnetic wave generated when an irradiation target having a measuring target is irradiated with a pre-irradiation electromagnetic wave and a reference electromagnetic wave having a repetition frequency different from a repetition frequency of the pre-irradiation electromagnetic wave by a predetermined differential frequency;
an accumulating and averaging section arranged to accumulate interference waveforms, by a number of every one or more, that the interference signal has and to output an averaged result of the accumulation;
a frequency spectrum outputting section arranged to output a frequency spectrum of an output from the accumulating and averaging section;
an optical frequency spectrum converting section arranged to convert the frequency spectrum into an optical frequency spectrum; and
an optical frequency spectrum average outputting section arranged to output an averaged result of the optical frequency spectrum.

2. The electromagnetic wave measuring apparatus according to claim 1, wherein the number is fixed.

3. The electromagnetic wave measuring apparatus according to claim 1, wherein
the number is variable, and
the optical frequency spectrum average outputting section is arranged to output an averaged result of the optical frequency spectrum weighted by the number.

4. The electromagnetic wave measuring apparatus according to claim 1, wherein
a plurality of the frequency spectrum outputting sections are provided, and
the frequency spectrum outputting sections are each arranged to output a frequency spectrum of an averaged result of the accumulation for each separate group of interference waveforms.

5. The electromagnetic wave measuring apparatus according to claim 1, wherein
the optical frequency spectrum average outputting section is arranged to output an ensemble averaged result of the optical frequency spectrum.

6. The electromagnetic wave measuring apparatus according to claim 1, wherein
waveforms of the post-irradiation electromagnetic wave are acquired by dual-comb spectroscopy.

7. The electromagnetic wave measuring apparatus according to claim 1, wherein
waveforms of the post-irradiation electromagnetic wave are acquired by terahertz time domain spectroscopy.

8. The electromagnetic wave measuring apparatus according to claim 1, wherein
waveforms of the post-irradiation electromagnetic wave are acquired by pump-probe method.

9. The electromagnetic wave measuring apparatus according to claim 1, wherein
the irradiation target is gas.

10. The electromagnetic wave measuring apparatus according to claim 9, wherein
the irradiation target is housed in a gas cell.

11. The electromagnetic wave measuring apparatus according to claim 10, wherein
a concentration of the measuring target is measured.

12. The electromagnetic wave measuring apparatus according to claim 1, wherein
the irradiation target is liquid or solid.

13. The electromagnetic wave measuring apparatus according to claim 12, wherein
a presence of the measuring target is measured.

14. An electromagnetic wave measuring method, comprising:
acquiring an interference signal between a post-irradiation electromagnetic wave generated when an irradiation target having a measuring target is irradiated with a pre-irradiation electromagnetic wave and a reference electromagnetic wave having a repetition frequency different from a repetition frequency of the pre-irradiation electromagnetic wave by a predetermined differential frequency;
accumulating interference waveforms, by a number of every one or more, that the interference signal has;
outputting an averaged result of the accumulating;
outputting a frequency spectrum of an output from the outputting of the averaged result;
converting the frequency spectrum into an optical frequency spectrum; and
outputting an averaged result of the optical frequency spectrum.

15. A non-transitory computer-readable medium including a program of instructions for execution by a computer to perform an electromagnetic wave measuring process with using an electromagnetic wave measuring apparatus including an interference signal acquiring section arranged to acquire an interference signal between a post-irradiation electromagnetic wave generated when an irradiation target having a measuring target is irradiated with a pre-irradiation electromagnetic wave and a reference electromagnetic wave having a repetition frequency different from a repetition frequency of the pre-irradiation electromagnetic wave by a predetermined differential frequency,
the electromagnetic wave measuring process, comprising:
accumulating interference waveforms, by a number of every one or more, that the interference signal has;
outputting an averaged result of the accumulating;
outputting a frequency spectrum of an output from the outputting of the averaged result;
converting the frequency spectrum into an optical frequency spectrum; and
outputting an averaged result of the optical frequency spectrum.
